(19) United States
(12) Patent Application Publication
(10) Pub. No.: US 2006/0134923 A1
(43) Pub. Date: Jun. 22, 2006

(54) Semiconductor substrate cleaning apparatus and method

(76) Inventors: Yoshihiro Ogawa, Yokohama-Shi (JP); Hiroshi Tomita, Yokohama-Shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/260,272

(22) Filed: Oct. 28, 2005

(30) Foreign Application Priority Data
Oct. 29, 2004 (JP) 2004-316025

(51) Int. Cl. H01L 21/306; H01L 21/302

(52) U.S. Cl. 438/745; 156/345.1

(57) ABSTRACT

According to the present invention, there is provided a semiconductor substrate cleaning apparatus comprising: a support which supports a semiconductor substrate; a rotating mechanism which rotates the semiconductor substrate; a first supply unit which supplies a first treatment liquid to which an ultrasonic wave is added, to a surface, on which no circuit pattern is formed, of the semiconductor substrate; and a second supply unit which supplies a second treatment liquid to an edge of a surface, on which a circuit pattern is formed, of the semiconductor substrate.

### CROSS REFERENCE TO RELATED APPLICATION

This application is based upon and claims benefit of priority under 35 USC §119 from the Japanese Patent Application No. 2004-316025, filed on Oct. 29, 2004, the entire contents of which are incorporated herein by reference.

### BACKGROUND OF THE INVENTION

The present invention relates to a semiconductor substrate cleaning apparatus and method.

In the semiconductor fabrication process, a cleaning step is repetitively performed in order to ensure the yield.

One cleaning method used in this cleaning step is single-wafer ultrasonic cleaning by which a cleaning solution to which an ultrasonic wave is added is sprayed against a semiconductor substrate from a nozzle, thereby cleaning one semiconductor substrate at one time.

Unfortunately, this single-wafer ultrasonic cleaning has the problem that microfabricated circuit patterns are damaged because the cleaning solution to which an ultrasonic wave is added is directly sprayed against the entire surface of a semiconductor substrate.

In addition, no dust control is performed on a bevel (the edge of a semiconductor substrate) in which no circuit patterns are formed, so contamination on this bevel cannot be removed in some cases.

In this case, if batch ultrasonic cleaning by which a plurality of semiconductor substrates dipped in a cleaning solution are cleaned by adding an ultrasonic wave to the cleaning solution is performed after single-wafer ultrasonic cleaning, dust remaining on the bevel after single-wafer ultrasonic cleaning is performed moves to the surface (on which circuit patterns are formed) of each semiconductor substrate during batch ultrasonic cleaning, thereby producing a killer defect (dust) and decreasing the yield.

The names of references concerning semiconductor substrate ultrasonic cleaning are as follows.

Reference 1: Japanese Patent Laid-Open No. 11-300301

Reference 2: Japanese Patent Laid-Open No. 2001-259550

### SUMMARY OF THE INVENTION

According to one aspect of the present invention, there is provided a semiconductor substrate cleaning apparatus comprising:
a support which supports a semiconductor substrate;
a rotating mechanism which rotates the semiconductor substrate;
a first supply unit which supplies a first treatment liquid to which an ultrasonic wave is added, to a surface, on which no circuit pattern is formed, of the semiconductor substrate; and
a second supply unit which supplies a second treatment liquid to an edge of a surface, on which a circuit pattern is formed, of the semiconductor substrate.

According to one aspect of the present invention, there is provided a semiconductor substrate cleaning apparatus comprising:
a support which supports a semiconductor substrate;
a rotating mechanism which rotates the semiconductor substrate;
a supply unit which supplies a treatment liquid to which an ultrasonic wave is added, to a surface, on which no circuit pattern is formed, of the semiconductor substrate; and
a controller which controls a rotational speed of the semiconductor substrate rotated by said rotating mechanism, thereby adjusting a moving amount by which the treatment liquid supplied to the surface on which no circuit pattern is formed moves to an edge of a surface on which a circuit pattern is formed.

According to one aspect of the present invention, there is provided a semiconductor substrate cleaning method comprising:
supporting a semiconductor substrate;
rotating the semiconductor substrate; and
supplying a first treatment liquid to which an ultrasonic wave is added, to a surface, on which no circuit pattern is formed, of the semiconductor substrate, and supplying a second treatment liquid to an edge of a surface on which a circuit pattern is formed, or
supplying a first treatment liquid to which an ultrasonic wave is added, to a surface, on which no circuit pattern is formed, of the semiconductor substrate, and controlling a rotational speed of the semiconductor substrate, thereby adjusting a moving amount by which the treatment solution supplied to the surface on which no circuit pattern is formed moves to an edge of a surface on which a circuit pattern is formed.

### BRIEF DESCRIPTION OF THE DRAWINGS

FIG. 1 is a block diagram showing the arrangement of an ultrasonic cleaning apparatus according to an embodiment of the present invention;

FIG. 2 is a longitudinal sectional view showing the way the ultrasonic cleaning apparatus performs ultrasonic cleaning;

FIG. 3 is a graph showing the relationship between the dissolved gas concentration and the particle removal ratio;

FIG. 4 is a graph showing the relationship between the input power and sound pressure value of an ultrasonic vibrator;

FIG. 5 is a graph showing the relationship between the distance from the center of a semiconductor substrate and the film thickness of a silicon nitride film;

FIG. 6 is a graph showing the relationship between the distance from the center of a semiconductor substrate and the film thickness of a silicon oxide film;

FIG. 7 is a longitudinal sectional view showing a shielding plate of an ultrasonic cleaning apparatus according to another embodiment.

### DETAILED DESCRIPTION OF THE INVENTION

Embodiments of the present invention will be described below with reference to the accompanying drawings.

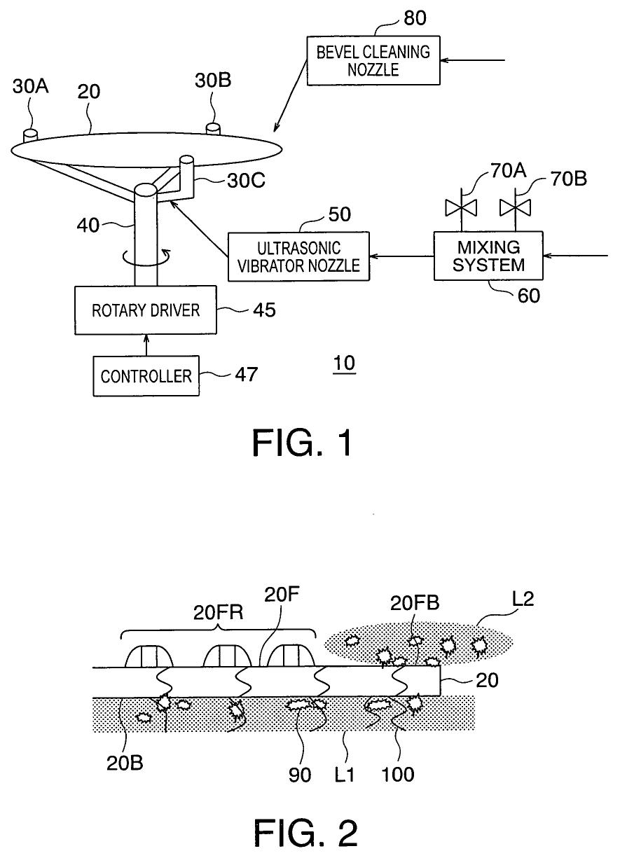

FIG. 1 shows a single-wafer ultrasonic cleaning apparatus 10 according to an embodiment of the present invention. The ultrasonic cleaning apparatus 10 is used in a single-wafer cleaning step of ultrasonically cleaning one semiconductor substrate 20 at one time. That is, the ultrasonic cleaning apparatus 10 performs a cleaning process of the semiconductor substrate 20, a rinsing process of washing away a cleaning solution sticking to the semiconductor substrate 20, and a drying process in order.

This single-wafer cleaning step is performed before a batch cleaning step of cleaning a plurality of semiconductor substrates at once, in order to suppress an increase in dust in this batch cleaning step. In the semiconductor fabrication process, the single-wafer cleaning step is performed after a film formation step or lithography step.

The ultrasonic cleaning apparatus 10 has a support 30 having a plurality of support pins 30A to 30C for supporting the semiconductor substrate 20. The support 30 supports the circumferential surface of the semiconductor substrate 20 by the support pins 30A to 30C, thereby supporting the semiconductor substrate 20 with its surface (on which circuit patterns are formed) facing up.

Note that the support pins 30A to 30C are arranged at predetermined intervals along the circumferential surface of the semiconductor substrate 20, and made of an elastic member which urges the circumferential surface of the semiconductor substrate 20 toward the center.

A rotating mechanism of the semiconductor substrate 20 includes a rotating shaft 40 and rotary driver 45. The rotating shaft 40 is attached to the support pins 30A to 30C, and rotated by the rotary driver 45. Note that the rotational speed of the rotary driver 45 is controlled by a controller 47.

To clean the semiconductor substrate 20, therefore, the ultrasonic cleaning apparatus 10 rotates the rotating shaft 40 to rotate the support 30 having the support pins 30A to 30C around the rotating shaft 40, thereby horizontally rotating the semiconductor substrate 20.

Note that the semiconductor substrate 20 may also be rotated by supporting it by holding its back surface by vacuum suction.

An ultrasonic vibrator nozzle 50 containing an ultrasonic vibrator is positioned below the back surface (on which no circuit patterns are formed) of the semiconductor substrate 20. Note that the frequency of this ultrasonic vibrator is set at 500 kHz or more to effectively perform a cleaning process.

In the cleaning process, a mixing system 60 opens valves 70A and 70B to dissolve ammonium hydroxide (NH₄OH) and hydrogen peroxide (H₂O₂) in pure water supplied from a treatment solution supply source (not shown), and supplies the obtained solution as a cleaning solution to the ultrasonic vibrator nozzle 50.

Note that the cleaning solution need only be a liquid chemical prepared by dissolving, in pure water, ammonium hydroxide (NH₄OH), choline, tetramethylammoniumhydroxide (TM—AH), hydrogen peroxide (H₂O₂), hydrogen chloride (HCl), ozone (O₃) water, or a combination of these materials, and may also be pure water.

The ultrasonic vibrator nozzle 50 adds an ultrasonic wave to this cleaning solution, and sprays the cleaning solution to which the ultrasonic wave is added against the entire back surface of the semiconductor substrate 20 in rotation, thereby cleaning the back surface of the semiconductor substrate 20.

Above the front surface of the semiconductor substrate 20, on the other hand, a bevel cleaning nozzle 80 for cleaning only the bevel (edge), on which no circuit patterns are formed, of the front surface of the semiconductor substrate 20 is placed.

The bevel cleaning nozzle 80 cleans the bevel by spraying a cleaning solution supplied from a treatment solution supply source (not shown) against the bevel of the semiconductor substrate 20 in rotation.

When thus completing the cleaning process, the ultrasonic cleaning apparatus 10 performs a rinsing process which washes away the cleaning solution sticking to the semiconductor substrate 20.

During this rinsing process, the ultrasonic cleaning apparatus 10 closes the valves 70A and 70B to supply pure water as a rinsing solution from the treatment solution supply source (not shown) to the ultrasonic vibrator nozzle 50.

The ultrasonic vibrator nozzle 50 adds an ultrasonic wave to this rinsing solution, and sprays the rinsing solution to which the ultrasonic wave is added against the entire back surface of the semiconductor substrate 20 in rotation, thereby rinsing the back surface of the semiconductor substrate 20.

On the other hand, the bevel cleaning nozzle 80 sprays pure water supplied from the treatment solution supply source (not shown) as the rinsing solution against the bevel of the semiconductor substrate 20 in rotation, thereby rinsing the bevel.

After sequentially performing the cleaning process and rinsing process as described above, the ultrasonic cleaning apparatus 10 dries the semiconductor substrate 20 by rotating it at a high speed.

FIG. 2 shows the way the ultrasonic cleaning apparatus 10 performs ultrasonic cleaning. As shown in FIG. 2, a liquid film L1 of the cleaning solution to which the ultrasonic wave is added is formed on the whole of a back surface 20B of the semiconductor substrate 20, and a liquid film L2 of the cleaning solution is formed only on a bevel 20FB of a front surface 20F of the semiconductor substrate 20.

In this state, cavitation (the formation of vacuum bubbles) 90 occurs in the liquid film L1 on the back surface 20B of the semiconductor substrate 20, and this removes particles (fine dust).

An ultrasonic wave 100 added to the cleaning solution attenuates as it is transmitted through the semiconductor substrate 20. Of the front surface 20F of the semiconductor substrate 20, no liquid film of the cleaning solution is formed in a region 20FR in which circuit patterns are formed, so no cavitation occurs in this region.

This makes it impossible to remove particles existing in the region 20FR of the semiconductor substrate 20 in which circuit patterns are formed. However, it is unnecessary to remove particles by possibly inflicting damage on microfabricated circuit patterns. As a consequence, damage to the circuit patterns can be prevented.

By contrast, since the liquid film L2 is formed on the bevel 20FB, in which no circuit patterns are formed, of the front surface 20F of the semiconductor substrate 20, cavitation occurs by the ultrasonic wave transmitted through the semiconductor substrate 20, so particles can be removed.

In the batch cleaning step performed after the single-wafer cleaning step, therefore, it is possible to suppress an increase in dust by preventing particles from moving from the bevel 20FB to the region 20 FR in which circuit patterns are formed. As a consequence, the yield can be increased.

Note that the ultrasonic cleaning apparatus 10 rotates the semiconductor substrate 20 at a high rotational speed of, e.g., 500 to 1,000 rpm. Accordingly, the removed particles can be easily discharged outside the semiconductor substrate 20, and do not move to the region 20FR in which circuit patterns are formed.

This is the case in which, for example, a silicon oxide film is formed on the semiconductor substrate 20 and an aqueous hydrogen fluoride (HF) solution is used as a liquid chemical. Although any liquid chemical and any film qualitatively show similar tendencies, the moving amount (absolute value) of the liquid changes in accordance with, e.g., the properties of the film on the front surface and the viscosity of the liquid. Therefore, the rotational speed is determined by taking account of the properties of the film on the front surface, the viscosity of the liquid chemical, and the like.

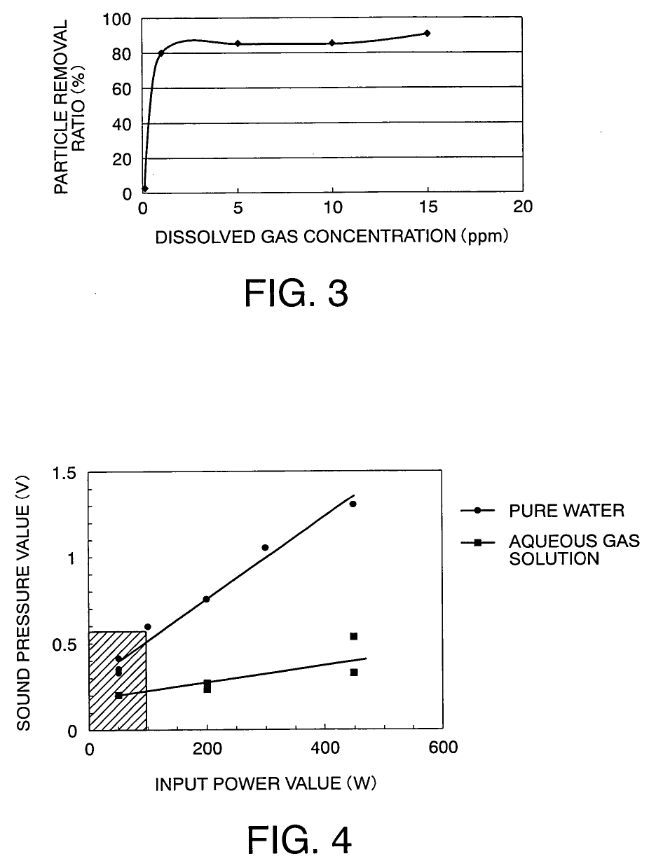

FIG. 3 shows the relationship between the concentration of a gas dissolved in ultrapure water (high-purity water) and the particle removal ratio when the ultrapure water is used as the cleaning solution. As shown in FIG. 3, when the ultrapure water is used as the cleaning solution, at least 1 ppm or more of, e.g., nitrogen, oxygen, or ozone is desirably dissolved in the ultrapure water in order to allow easy occurrence of cavitation, and increase the particle removal ratio.

FIG. 4 shows the relationship between the input power value, which is the product of the values of an electric current and voltage input to the ultrasonic vibrator, and the sound pressure value when ultrapure water or an aqueous gas solution prepared by dissolving 5 ppm of a gas such as ozone (O₃) in the ultrapure water is used as the cleaning solution. Referring to FIG. 4, a hatched portion indicates a region where no damage is inflicted on circuit patterns.

As shown in FIG. 4, circuit patterns are damaged if the input power of the ultrasonic vibrator is 100 W or more. To suppress damage to the circuit patterns, therefore, at least the sound pressure value is desirably set at 0.6 V or less.

The above embodiment can increase the yield.

Note that the above embodiment is merely an example and does not limit the present invention. For example, a cleaning solution to which an ultrasonic wave is added may also be sprayed only against the back surface 20B of the semiconductor substrate 20, without being sprayed against the front surface 20F of the semiconductor substrate 20.

In this case, the cleaning solution to which the ultrasonic wave is added can be moved from the back surface 20B to the bevel 20FB of the front surface 20F of the semiconductor substrate 20 by changing the rotational speed by, e.g., rotating the semiconductor substrate 20 at a low rotational speed of 100 rpm. Consequently, the bevel 20FB of the semiconductor substrate can be cleaned without spraying the cleaning solution against it.

The moving amount by which the cleaning solution to which the ultrasonic wave is added moves to the bevel 20FB of the front surface 20F of the semiconductor substrate 20 can be adjusted by finely adjusting the rotational speed.

In order to further adjust an area of the bevel 20FB to be cleaned, after cleaning is performed, it is possible to perform an additional rinsing process by spraying pure water supplied from the treatment solution supply source (not shown) as a rinsing liquid via the bevel cleaning nozzle 80 against the bevel 20FB of the semiconductor substrate 20. It is also possible to perform a rinsing process by cleaning the bevel 20FB of the front surface 20F of the semiconductor substrate 20 using the cleaning solution enhanced with the ultrasonic wave, while adjusting the moving amount, and simultaneously by spraying pure water supplied from the treatment solution supply source (not shown) as a rinsing liquid via the bevel cleaning nozzle 80 against the bevel 20FB of the semiconductor substrate 20.

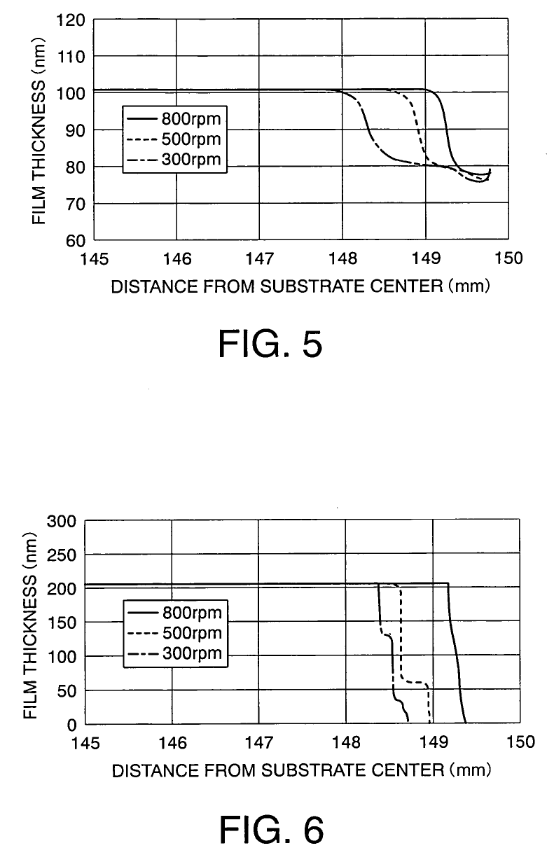

FIGS. 5 and 6 each show the film thickness of a film formed on the bevel 20FB of the semiconductor substrate 20 after the cleaning process is performed. That is, FIG. 5 shows the film thickness of a silicon nitride (SiN) film, and FIG. 6 shows the film thickness of a silicon oxide (SiO₂) film. Each film was obtained by treating the semiconductor substrate 20 having a diameter of 300 mm at a temperature of 65° C. for 15 sec by using an aqueous 40-wt % hydrogen fluoride (HF) solution. The abscissa indicates the distance from the center of the semiconductor substrate 20, and the ordinate indicates the film thickness of the film formed on the semiconductor substrate 20.

As shown in FIGS. 5 and 6, when the semiconductor substrate 20 is rotated at a low speed, the amount of cleaning solution which moves from the back surface 20B of the semiconductor substrate 20 to the bevel 20FB of the front surface 20F increases, and this increases the etching amount. Although any liquid chemical and any film qualitatively show similar tendencies, the moving amount (absolute value) of the liquid changes in accordance with, e.g., the properties of the film on the front surface and the viscosity of the liquid.

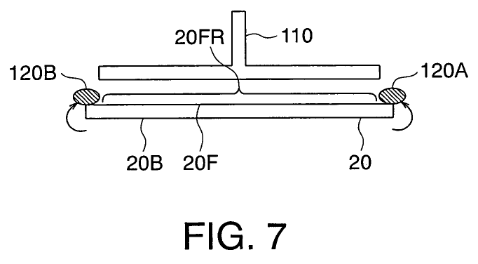

As shown in FIG. 7, a shielding plate (e.g., a shielding plate having a radius smaller by, e.g., 1 to 5 mm than that of the semiconductor substrate 20) 110 having a circumferential surface inside that of the semiconductor substrate 20 may also be positioned at a predetermined distance (e.g., about 1 mm or less) from the semiconductor substrate 20. By making the rotational speed of the shielding plate 110 substantially the same as that of the semiconductor substrate 20 by a shielding plate rotating mechanism (not shown), it is possible to limit ranges 120A and 120B over which the cleaning solution to which the ultrasonic wave is added moves from the back surface 20B to the front surface 20F of the semiconductor substrate 20.

In this case, by spraying nitrogen gas or the like from the shielding plate 110 toward the front surface 20F of the semiconductor substrate 20, it is possible to reliably prevent the cleaning solution from moving to the region 20FR, in which circuit patterns are formed, of the front surface 20F of the semiconductor substrate 20.

What is claimed is:

1. A semiconductor substrate cleaning apparatus comprising:
a support which supports a semiconductor substrate;
a rotating mechanism which rotates the semiconductor substrate;
a first supply unit which supplies a first treatment liquid to which an ultrasonic wave is added, to a surface, on which no circuit pattern is formed, of the semiconductor substrate; and
a second supply unit which supplies a second treatment liquid to an edge of a surface, on which a circuit pattern is formed, of the semiconductor substrate.

2. An apparatus according to claim 1, wherein each of the first and second treatment liquid is one of a predetermined liquid chemical and pure water.

3. An apparatus according to claim 1, wherein the edge is a region, where the circuit pattern is not formed, of the surface on which the circuit pattern is formed.

4. An apparatus according to claim 1, wherein said first supply unit supplies the first treatment liquid to which an ultrasonic wave having a frequency of not less than 500 kHz is applied.

5. An apparatus according to claim 1, wherein said first supply unit supplies the first treatment liquid to which an ultrasonic wave having a sound pressure of not more than 0.6 V is applied.

6. A semiconductor substrate cleaning apparatus comprising:
a support which supports a semiconductor substrate;
a rotating mechanism which rotates the semiconductor substrate;
a supply unit which supplies a treatment liquid to which an ultrasonic wave is added, to a surface, on which no circuit pattern is formed, of the semiconductor substrate; and
a controller which controls a rotational speed of the semiconductor substrate rotated by said rotating mechanism, thereby adjusting a moving amount by which the treatment liquid supplied to the surface on which no circuit pattern is formed moves to an edge of a surface on which a circuit pattern is formed.

7. An apparatus according to claim 6, further comprising:
a shielding plate positioned at a predetermined distance from the semiconductor substrate and having a radius smaller by a predetermined amount than a radius of the semiconductor substrate; and
a rotating mechanism which rotates said shielding plate, wherein said controller controls said shielding plate rotating mechanism to make a rotational speed of said shielding plate substantially the same as a rotational speed of the semiconductor substrate.

8. An apparatus according to claim 6, wherein the treatment liquid is one of a predetermined liquid chemical and pure water.

9. An apparatus according to claim 6, wherein the edge is a region, where the circuit pattern is not formed, of the surface on which the circuit pattern is formed.

10. An apparatus according to claim 6, wherein said supply unit supplies the treatment liquid to which an ultrasonic wave having a frequency of not less than 500 kHz is applied.

11. An apparatus according to claim 6, wherein said supply unit supplies the treatment liquid to which an ultrasonic wave having a sound pressure of not more than 0.6 V is applied.

12. A semiconductor substrate cleaning method comprising:
supporting a semiconductor substrate;
rotating the semiconductor substrate; and
supplying a first treatment liquid to which an ultrasonic wave is added, to a surface, on which no circuit pattern is formed, of the semiconductor substrate, and supplying a second treatment liquid to an edge of a surface on which a circuit pattern is formed, or
supplying a first treatment liquid to which an ultrasonic wave is added, to a surface, on which no circuit pattern is formed, of the semiconductor substrate, and controlling a rotational speed of the semiconductor substrate, thereby adjusting a moving amount by which the treatment solution supplied to the surface on which no circuit pattern is formed moves to an edge of a surface on which a circuit pattern is formed.

13. A method according to claim 12, wherein when the first treatment liquid are supplied, one of a predetermined liquid chemical and pure water is supplied.

14. A method according to claim 12, wherein when the second treatment liquid is supplied, the second treatment liquid is supplied to the edge, which is a region where the circuit pattern is not formed, of the surface on which the circuit pattern is formed.

15. A method according to claim 12, wherein when the first treatment liquid is supplied, the first treatment liquid to which an ultrasonic wave having a frequency of not less than 500 kHz is applied is supplied.

16. A method according to claim 12, wherein when the first treatment liquid is supplied, the first treatment liquid to which an ultrasonic wave having a sound pressure of not more than 0.6 V is applied is supplied.

17. A method according to claim 12, wherein when the moving amount is adjusted, a shielding plate positioned at a predetermined distance from the semiconductor substrate and having a radius smaller by a predetermined amount than a radius of the semiconductor substrate is rotated at a speed higher than a speed of the semiconductor substrate.

18. A method according to claim 12, wherein when the moving amount is adjusted, an amount which moves to the edge, which is a region where the circuit pattern is not formed, of the surface on which the circuit pattern is formed is adjusted.
